(19) United States
(12) Patent Application Publication
(10) Pub. No.: US 2021/0333713 A1
(43) Pub. Date: Oct. 28, 2021

(54) APPARATUS FOR AND METHOD OF MANUFACTURING AN ARTICLE USING PHOTOLITHOGRAPHY AND A PHOTORESIST

(71) Applicants: Andrea Jocelyn Bubendorfer, Lower Hutt (NZ); Andrew David Best, Lower Hutt (NZ); Callaghan Innovation, Lower Hutt (NZ)

(72) Inventors: Andrea Jocelyn Bubendorfer, Lower Hutt (NZ); Andrew David Best, Lower Hutt (NZ)

(21) Appl. No.: 17/273,410

(22) PCT Filed: Sep. 6, 2019
(86) PCT No.: PCT/NZ2019/050116

§ 371 Date: Mar. 4, 2021

(30) Foreign Application Priority Data
Sep. 6, 2018 (NZ) 746127

(51) Int. Cl. G03F 7/09; G03F 7/20; G03F 7/095; G03F 7/004

(52) U.S. Cl. CPC G03F 7/094; G03F 7/70008; G03F 7/0047; G03F 7/095; G03F 7/70808

(57) ABSTRACT

An apparatus is provided configured to manufacture an article using a multi-layer/laminated photoresist comprising a plurality of layers of photoresist material, where at least a first layer of photoresist material has a first sensitivity to radiation, and at least a second layer of photoresist material has a different sensitivity to radiation. The apparatus comprises: a. a housing configured to receive the photoresist and locate the photoresist in at least one operational position in the housing; b. an exposure system configured to emit radiation which is incident on the photoresist when in the operational position; wherein: i. the exposure system is configured to emit radiation having a first radiation characteristic to induce a change in one or more properties of the area(s) of the first layer of photoresist material exposed to the radiation; and wherein ii. the first radiation characteristic is configured not to induce a change, or to induce a different change, in one or more properties of at least a different one of the layers of photoresist material. Consequently complex articles can be manufactured including hidden or partially visible features, such as overhangs for example.

### BACKGROUND OF THE DISCLOSURE

### Field of the Disclosure

The present disclosure generally relates to an apparatus for and method of manufacturing an article using photolithography and a photoresist. In some examples the apparatus and method use a dry film photoresist. An example photoresist is as described in patent application US2006/0257785, the entire contents of which are incorporated herein by reference. This disclosure stems from some further work in developing the apparatus and method disclosed in our earlier patent application PCT/NZ2018/050030, the entire contents of which are hereby incorporated by reference.

### Description of the Related Art

In one prior art example, a liquid solution of photoresist material is spun onto a wafer or substrate and then prebaked. The photoresist is then exposed to light in the pattern desired. This causes a chemical change in the photoresist which allows the photoresist to be removed via a developer which is typically a liquid such as sodium hydroxide solution for a positive resist, or a solvent such as propylene glycol monomethyl ether acetate for a negative resist. Typically a negative photoresist is baked before the developer is applied. A positive photoresist is one where the photoresist is made more soluble by exposure to light and is removed by the developer. A negative photoresist is one in which the unexposed areas are removed by the developer. The negative photoresist may be chemically amplified or not. An image reversal resist, which may be used for either positive or negative toned patterning may also be used. There can be further post developing steps such as hard baking after the developer is applied, and/or etching whereby part of the substrate is removed in the areas where the photoresist has been removed.

It is also known to provide a photoresist material as a composite film comprising a polymer film and a dried coating of photoresist material, which composite film is itself applied to a substrate using heat and pressure. The polymer film can then be removed, leaving the photoresist material on the substrate. Such composite films are typically known as dry film photoresists. An example of such a dry film photoresist is disclosed in US2006/0257785 as described above. Such a dry film photoresist is typically supplied as a photoresist material sandwiched between a base polymer film/sheet and a protective cover film/sheet. The polymer film may, depending on its material and configuration, itself function as a substrate during the photolithographic process. Such dry film photoresists can be easier to handle than the liquid forms, can enable different substrate material to be used, can be thicker, and can be processed more quickly.

Nonetheless, whether conventional or dry film photoresists are used, there can be considerable difficulty, precision, time and expense in producing structures using the above described process, and production of free-standing parts has typically been difficult to achieve. Our earlier patent application PCT/NZ2018/050030, discloses an apparatus and method directed at alleviating one or more of these problems.

There can be a limitation in the ability to print structures without patterning previously patterned layers underneath.

For example, when 3D printing objects there are many instances where it may be desirable to create an overhanging feature. For example, the ability to print active structures such as cantilevers is desirable as these form the basis of many sensors.

When using a light source to create an overhanging feature one needs to prevent or control the light source from going too deep into the structure, further exposing underlying layers, or beyond where the feature is required. Conflictingly, it is also necessary to provide enough intensity to create/crosslink the feature. This creates a limitation of the Z or depth resolution of about 125 μm with current printing technologies.

The steps for manufacturing an article as described in our earlier patent application PCT/NZ2018/050030 are, in summary: expose to radiation (with a shutter to prevent patterning of the underlying layers), align the desired layers of photoresist material and then laminate those layers together. This technique allows a Z resolution of the thickness of the dry film photoresist—down to around 5 μm.

However, a further problem is that to align the exposed layer requires mechanical alignment which is difficult to do accurately. The layer is then is also subject to the forces of a lamination which can distort at least a pattern used to identify the shape of the article to be produced.

### SUMMARY OF THE DISCLOSURE

It is an object of the present disclosure to provide an apparatus and method for manufacturing an article using photolithography and one or more photoresists, and/or that will alleviate one or more of the above problems and/or that will at least provide the public with a useful choice.

Accordingly in one aspect the disclosure may broadly be said to consist of an apparatus configured to manufacture an article using a multi-layer/laminated photoresist comprising a plurality of layers of photoresist material, where at least a first layer of photoresist material has a first sensitivity to radiation, and at least a second layer of photoresist material has a different sensitivity to radiation, the apparatus comprising:
a housing configured to receive the photoresist and locate the photoresist in at least one operational position in the housing;
an exposure system configured to emit radiation which is incident on the photoresist when in the operational position; wherein:
   the exposure system is configured to emit radiation having a first radiation characteristic to induce a change in one or more properties of the area(s) of the first layer of photoresist material exposed to the radiation; and wherein
   the first radiation characteristic is configured not to induce a change, or to induce a different change, in one or more properties of at least a different one of the layers of photoresist material.

The exposure system may be configured to emit radiation having a second radiation characteristic, which is different to the first radiation characteristic, to induce a change in one or more properties of the area(s) of at least a different one of the layers of photoresist material exposed to the radiation.
The apparatus may comprise a heater configured to heat the photoresist material to cure the photoresist material when the photoresist is in the operational position, or is in a different operational position in the housing.
The housing may be radiation excluding such that external radiation cannot enter the housing at least to the extent that the external radiation is sufficiently excluded from the housing to prevent, or minimise polymerisation of the photoresist material, and further
wherein the housing is a clean housing configured to prevent unwanted contamination from entering the housing, at least when the photoresist is located in the or each operational position.
The apparatus may be either configured to receive the multi-layer/laminated photoresist, or further comprises means to pre-laminate the multiple layers of photoresist material to form the multi-layer/laminated photoresist, prior to the multi-layer/laminated photoresist being exposed to radiation from the exposure system.
The first and second radiation characteristic of the radiation emitted by the exposure system may be any one or more of the:
   a) intensity of the radiation;
   b) wavelength of the radiation;
   c) duration of the radiation;

The apparatus may be configured to use a dry film photoresist.

The apparatus may comprise multiple exposure sources, each source configured to emit radiation having a different radiation characteristic.

The exposure source may be configured or may be controlled to selectively emit radiation having different radiation characteristics.

The housing may be configured to be UV excluding, and/or to exclude any other wavelength or range of wavelengths of radiation.

The apparatus may comprise components, assemblies and/or combinations of components and/or assemblies configured to provide any one or more of:
a) controlled actuation for the purpose of photoresist combination and layering;
b) controlled separation of processed photoresist from unprocessed photoresist;
c) removal of processed photoresist from a defined area of processing;
d) alignment and placement of the photoresist controlled.

In some examples the apparatus may be configured to use a dry film photoresist and/or may be configured to receive photoresist comprising one or more removable cover sheets, the apparatus being configured to remove the cover sheets prior to the photo resist reaching the operational position.

The apparatus may be dimensioned so as to be hand portable. The apparatus may be dimensioned and configured as a desk-top apparatus, or at least to be floor mounted. In some examples the overall external dimensions of width, height and length of the apparatus may each be less than 1 m, and in some examples less than 0.75 m, that is, approximately the size of an office type floor standing laser printer.

The radiation excluding/blocking housing may be configured to allow a portion of non-damaging visible light to be seen, thereby providing direct visible feedback as to the current status of the operation of the apparatus to the user. In other words the status of the processing of the photoresist may be safely observed externally of the housing. In other examples, the apparatus may be configured to generate a visual or audible signal indicative of the status of processing.

In some examples, the apparatus is configured to manufacture an article with feature sizes of 0.5 microns or less, 2 microns or less, four microns or less, or 20 microns or less, and/or a scale of at least 1 cm, 5 cm, 10 cm, 15 centimetres, or 50 cm or more. The resolution achieved may be determined in relation to the pixel size of the exposure system.

The exposure system preferably comprises at least one exposure source. The exposure system may comprise multiple exposure sources. The exposure source can be any suitable radiation source such as a light source. The light source may comprise any one or more of a UV fluorescent tube or bulb, an LED or LED array, a laser, and/or a projector such as a digital micromirror device (DMD), for example. The exposure source can emit radiation at any high energy electromagnetic frequency including X-ray, deep, mid or near UV, through to visible light. The exposure source may be configured to emit radiation in a wavelength range of 300-450 nm, and in some examples in a range of 365-405 nm. The exposure source may be collimated. The collimation may be performed by a lens, or paraboloid reflector, for example. The exposure source can be positioned within the apparatus either above or below the substrate of the photoresist and can emit radiation onto either or both of the topside or the underside of the substrate.

The exposure system may include one or more radiation manipulators configured to manipulate the radiation between the exposure source and the photoresist. The radiation manipulators could include any one or more of, for example, a mirror, a digital mirror, a prism, a lens, and/or a beam splitter. In some examples multiple radiation manipulators are provided. The multiple radiation manipulators may be provided in series or parallel configuration along the radiation path between the exposure source and the photoresist, that is, the operational position of the apparatus.

The exposure system may comprise one or more passive radiation manipulators and/or one or more dynamic or active radiation manipulators.

The exposure system may include one or more dynamic radiation manipulator configured to manipulate the radiation between the exposure source and the photoresist. The dynamic radiation manipulator could include any one or more of, for example, a digital mirror, an LCD, a galvanometer and/or an optomechanical laser system. In some examples multiple radiation manipulators are provided. The multiple radiation manipulators may be provided in series or parallel configuration along the radiation path between the exposure source and the photoresist. Before and/or after the dynamic radiation manipulator additional manipulators can be included, such as but not limited to, lenses, mirrors, or beam splitters.

In some embodiments, the length of the radiation path between the exposure source and the operational position of the photoresist is adjustable. In such embodiments the apparatus may therefore comprise a radiation path length adjuster configured to move one or both of the operational position of the photoresist and the position of the exposure source. In some embodiments the radiation path length adjuster comprises a platform on which the photoresist is located when in the operational position, the platform being movably mounted within the apparatus. The platform may comprise, or be coupled to, the heater.

In some examples, the platform and exposure source may both be movably mounted on the apparatus. The platform and exposure source may be configured to move together such that movement of the platform also moves the exposure source. The platform and the exposure source may be mounted on a carriage, the carriage being movably mounted on a linear element such as a track.

The heater could comprise any one or more of:
a) a heater plate on which the photoresist is placed when in the operational position;
b) a heater plate configured to be movable into a position adjacent or in contact with the photoresist when in the operational position;
c) an infrared heat source configured to radiate the photoresist; and/or
d) an oven in which the photoresist is located when in the operational condition.

The apparatus may comprise one or more controllers configured to control the exposure system and/or the heater.

The or one of the controller(s) may be configured to control any one or more of:
a) the intensity, and/or duration and/or timing of the radiation emitted from the exposure system; and/or
b) any one or more of the temperature, duration, timing and/or heating/cooling rate of the heater.
c) an exposure profile and/or a heater profile;
d) actuation elements such as those yielding thermal or mechanical functionality.
e) processing of feedback derived from sensors located in or on the apparatus;
f) the relative position between the exposure system and the operational position;
g) the relative position between the heater and the operational position.

The heater profile may be, for example approximately 10 mins at approximately 100° C. The exposure profile may be approximately 395 nm for approximately four minutes per layer of the 20 μm film. The exposure profile may be dependent on the power of the exposure system.

The controller preferably comprises a user interface. The controller may be configured to receive one or more inputs indicative of one or more properties of the article to be manufactured and/or of the dry film photoresist, and to control the exposure system profile and/or heater profile accordingly. In one example, the controller is configured to receive a single input being the thickness of the dry film photoresist. Any one or more of the input(s) to the controller may be a manual input entered by the user or a measured input determined from one or more sensors provided in or on the apparatus. The controller may be user programmable such that the user can configure one or more parameters of the controller. For example, the controller could control parameters relating to any one or more of:
a) thickness of photoresist (that is, the thickness of layer, in the z or vertical direction);
b) changes to exposure and/or heat profile to optimise processing if required;
c) the status of the apparatus. For example whether the apparatus is in an exposure, heating or cooling part of the process, how long until the program is finished, and rate of heating and/or cooling.

The controller may include one or more microcontrollers. Each controller may comprise any one or more of: an electronic data processor, a manual switched input and a timer.

The apparatus may further comprise a developer unit configured to deliver a developer fluid to the photoresist being processed so as to develop the photoresist after curing by the heater to remove either any photoresist material exposed to the developer fluid, or to remove any substrate. In some examples, the substrates do not have an oxide layer between the substrate and the photoresist. When free-standing structures are made, a PET or other backing sheet is simply mechanically removed, or, if easier for developing depending on the pattern, it may remain in place to support the structures through the development and be removed afterwards. Substrates with oxide layers could also be used with this system.

In some embodiments a tank of developer fluid is provided inside the housing. In other examples, the tank of developer fluid is separate from the apparatus and/or at least in communication with the inside of the housing. In some embodiments the developer fluid is exposed to the photoresist via a dispenser configured to dispense developer fluid onto the photoresist. Developer fluid may be dispensed in a mist or spray through one or more nozzles for example. In other embodiments, the apparatus is configured to soak or bathe the photoresist in developer fluid. This may be achieved in the developer tank or in a secondary tank or bath in fluid communication with the developer tank. The photoresist may be moved from the operational position, into a further operational position being a developer position in which the photoresist can be exposed to the developer fluid. In other embodiments, the photoresist remains in the operational position and developer fluid is subsequently applied to the photoresist after curing by the heater. The developer unit can comprise an integral component of the housing, and may be an internal or external component. The developer unit may be removeably mounted on the housing. A removable developer unit can be removed after use and either replenished with developer fluid or replaced. The developer system could recycle developer by using the inbuilt UV source or another UV source to cross-link and remove unpatterned resist. The developer system could be a zero waste system by extracting uncross-linked material from the developer in such a way that it may be reconstituted for further use, e.g. by precipitation or centrifugation for example.

The developer fluid may comprise hot water or another heated or non-heated fluid. The fluid may melt, or dissolve away bulk uncross-linked material, such that the uncross-linked material is easier to remove. The hot water or other fluid may use surfactants to break up and remove unused material. The fluid may be contained in one or more baths. The bath may be the cartridge in which the photoresist is exposed, or a separate secondary cartridge so as to isolate developer from the user. The fluid may be heated by the heater, or by another heat source which may be internal or external of the housing. The heat source may include a microwave source for example.

In some examples, the exposure system and the heater may be configured to be operative sequentially. In other examples, the exposure system and the heater may be configured to be operative concurrently. The exposure system may therefore be operative to emit radiation whilst the heater is on. The exposure system and heater may each be configured to be switched on and off at the same time as the other, or may be configured to be operative for a period which overlaps with the other.

The apparatus may comprise or further comprise a patterning system configured to enable a desired pattern to be applied to the photoresist. In some examples the patterning system may comprise a pattern formed or depicted on a protective sheet of, or applied to the photoresist. In other examples, the patterning system may comprise one or more photomasks positioned, or configured to be positioned, between the exposure system and the photoresist. The patterning system may be positioned, or configured to be positioned, in direct contact with the photoresist, such that there is no gap or space between the photoresist and the patterning system, either caused by air, or by the thickness of the protective sheet. High resolution structures of four micrometres or less may be formed by laminating directly to a high quality photomask. In other examples, the patterning system may comprise an electronic/optical/digital system configured to generate a pattern on the photoresist. The disclosure therefore includes the use of a glass photomask as a method of patterning, but also the possibility of making photo-patterns, such as films and photo-plates, either with a digital exposure or from another film pattern or photoplate.

In other embodiments the apparatus is configured to contain or store a plurality of photoresists, each comprising a plurality of layers of photoresist material. Each photoresist could for example comprise two or more layers. The layers could be made of the same type of photoresist material in different thicknesses, and/or different types of photoresist. The apparatus may comprise a storage device configured to store a plurality of photoresists. The storage device may be configured to store the plurality of photoresists in a stack. The storage device may be removeably mounted on the apparatus. The storage device may be configured to store the plurality of photoresists in a roll or reel. The roll or reel of photo resists may be removably stored in a storage device comprising a radiation excluding housing comprising an outlet through which the photoresist is fed towards the operational position.

The apparatus may further comprise a photoresist feed device configured to feed one or more photoresists into the operational position within the housing of the apparatus. The feed device may be manually operated or may be automated. For example, the feed device could comprise a movable platform or carriage on which the photoresist is placed and inserted into the housing. A locking device may be provided to lock the photoresist in the operational position, at least until the processing steps are complete. In other examples the feed device may comprise one or more rotating elements, such as rollers or wheels, configured to feed a roll of photoresists into the housing. Multiple rotating elements may be provided, the photoresists being sandwiched between adjacent rotating elements. The or each rotating element may be configured to remove one or more cover sheets from the photoresist. The feed device may comprise at least one moving platform, substrate or belt to move the photoresist to the operational position. In some examples a pair of laterally spaced apart belts are provided, on which the photoresist rests as it is fed from the feed device. The belts may be toothed to engage with, and be driven by, one or more toothed rotating elements.

The apparatus may comprise a mechanism for the controlled compression/seizing of material motion which allows for regional processing. This mechanism may comprise a clamping mechanism for example. The clamping mechanism may comprise a clamping plate configured to selectively clamp the photoresist in the operational position. The clamping plate may be movably mounted on the apparatus so as to be movable between clamping and non-clamping positions. Any other suitable mechanism may be used. For example the mechanism may comprise one or more pinch rollers.

According to another aspect of the disclosure there is provided a multi-layer/laminated photoresist configured for use with the apparatus of any one of the above statements, the multi-layer/laminated photoresist comprising a plurality of layers of photoresist material, where a first layer of photoresist material has a first sensitivity to radiation, and at least a second layer of photoresist material has a different sensitivity to radiation.

The photoresist may comprise one or more cover sheets, wherein one or both cover sheets is removable.

The sensitivity to radiation may be related to any one or more of:
a) UV sensitivity;
b) layer thickness;
c) sensitivity to radiation intensity; and/or
d) sensitivity to radiation wavelength.

The sensitivity to radiation of at least one layer may be varied from at least one other layer by the inclusion of any one or more of the following in the at least one layer:
an optical dye capable of modifying UV absorption;
particles;

The particles may be selected from any one or more of the following materials, or composite particles comprising one or more of the following materials:
a) metal;
b) ceramic;
c) magnetic;
d) piezoelectric;
e) thermochromic;
f) photochromic;
g) antimicrobial;
h) any other functionalised nanomaterial.
The photoresist may comprise the same photopolymerization initiators in each layer but with different concentrations.
The photoresist my comprise different photopolymerization initiators in each layer.
The photoresist may comprise a top layer with a loading of nano-particles that have a selective absorption peak at a set wavelength.
The photoresist may comprise a top layer with a particle or dye loading that partially prevents deep exposure and/or exposure of the layer underneath depending on the intensity of the radiation.

The photoresist may comprise a substrate and/or a protective sheet known as carrier or cover sheets. Each film/sheet may be removable. The substrate may itself be applied to a rigid substrate. The carrier sheets may be used to maintain smoothness and flatness of the photoresist prior to as well as during exposure and heating. This may be particularly useful if the article to be manufactured is formed from multiple photoresists stacked in layers, where the carrier sheet holds the uncross-linked photoresist flat during processing, enabling subsequent layers to be laminated evenly and preventing slumping of patterns in those subsequent layers.

The substrate may be formed from any suitable material. Example materials include silicon, metal(s), polymer(s), paper(s) or other fabric(s), epoxies, or a base layer of dry film resists, or other photoresists, including other dry film resists or dried resist films coated from solution. Polymer substrates may be particularly advantageous due to their increased bonding affinity to photoresists, low cost, machineability and optical transparency. A base layer of photoresist bonded to a polymer substrate gives high adhesion where required, such as for the production of micromoulds.

According to another aspect of the disclosure there is provided a system for manufacturing an article using photoresist comprising a photoresist layer, the system comprising the apparatus of any of the above aspects of the disclosure, and a photoresist or photoresist cartridge of any of the above aspects of the disclosure. The apparatus may be of a modular consideration whereby upgrades or different applications or configurations or modules are interchangeable and may be added or removed.

According to another aspect of the disclosure there is provided a method of manufacturing an article using a multi-layer/laminated photoresist comprising a plurality of layers of photoresist material, where at least first layer of photoresist material has a first sensitivity to radiation, and at least a second layer of photoresist material has a different sensitivity to radiation, the method comprising steps of:
a. inserting the photoresist into a housing of a manufacturing apparatus;
b. using an exposure system in the housing to emit radiation which is incident on the photoresist material when in the operational position, wherein:
   i. the exposure system is configured to emit radiation having a first radiation characteristic to induce a change in one or more properties of the area(s) of the first layer of photoresist material exposed to the radiation; and wherein
   ii. the first radiation characteristic is configured not to induce a change, or to induce a different change, in one or more properties of at least a different one of the layers of photoresist material.

The method may comprise the further step of:
c. controlling a heater, also in the housing, to subsequently heat the photoresist material to cross link the photoresist material to the substrate.

The exposure system may be configured to emit radiation having a second radiation characteristic, different to the first radiation characteristic, to induce a change in one or more properties of the area(s) of at least a different one of the layers of photoresist material exposed to the radiation.

The housing is radiation excluding such that external radiation cannot enter the housing at least to the extent that the external radiation is sufficiently excluded from the housing to prevent, or minimise polymerisation of the photoresist material, at least when the photoresist is present, and further wherein the housing is a clean housing configured to prevent unwanted particles and/or other contaminants from entering the housing.

The photoresist layer can be either used as received as a dry film photoresist, or may be subject to a pre-processing step whereby the apparatus dries the photoresist layer by removal of the solvent, such that the dry photoresist can then be processed as above.

The method may allow the fabrication of aligned multilayer structures by a method that comprises of the steps of heating the photoresist to semi-cure a pattern only until a visible image is formed; then using the early visible image as an inbuilt reference maker to align one or more layers of the photoresist with another layer of the photoresist, and then subsequently fully curing the multiple layers of photoresists to cure together into a single cross-linked structure by use of any one or more of lamination, heat, pressure and/or plasma assistance for example. This may help to achieve high bond strength and good alignment where multiple photoresists are used to form the article.

The method may comprise a step of recombining multiple exposed and cured photoresists such that the photoresists occupy multiple planes or are inclined relative to one another, to produce a 3D structure. Additionally or alternatively such a step could be used to bond to solid blocks of epoxy (the base material of the negative photoresist) such that the articles produced are not limited to thin planar structures, or multi-layered flat laminated structures. One example could be a microscale pressure sensor that has relatively large relatively thick vertical side walls that could be assembled with relatively thick blocks of epoxy bound to a thin deformable membrane in a perpendicular plane. Another example could be the basis of an accelerometer sensor that used a fine microstructure coating on the walls of larger unpatterned blocks of epoxy.

The method may comprise a step of forming an active structure such as a cantilever, plate, bridge, or membrane, the four main examples of MEMS springs, for example, widely used for miniaturised sensors. These structures may be produced, by selectively bonding part of a layer of one photoresist to another to form a tether, with a flat smooth layer of uncross-linked photoresist material as a support to be removed during development, thus leaving another part of the first photoresist free to move, creating the active structure.

The method may comprise a step of forming conductive pathways or interfaces within the printed structures. In one example, a polymer coated metal or other conductive foil can then be bound to the polymer photoresist, and left in place. In other examples, conducting polymers, polymer coated foils or conductive photoresists or conductive inks may be interfaced with one or more layer of photoresist and left in place. The combination of the active structures with conductive elements as described, provides the ability to rapidly print low cost microsensors. The conductive pathways could comprise non-metal materials such as conducting polymers, semi-conductor material, and/or carbon nanotube loaded photoresists and/or other polymers.

The method may comprise the ability to deposit transducer materials as part of the microstructure, an example being the deposition of polyvinylidene difluoride, a piezoelectric transducer material, or other material that converts mechanical energy to electric energy, thus forming the ability to rapidly print microstructures such as energy harvesters.

The method may comprise the ability to combine active structures or microsensors with said formed transducer combinations, thus forming the ability to rapidly print self-powered sensors.

The method may comprise the ability to combine active structures with surface functionalisation, thus forming the ability to rapidly print microsensors for chemical detection for example.

The method may comprise one or more steps of forming a curved structure, such as a lens, or a lens array for example. This may be achieved by exposing the area around the lens (the negative lens space), then heating to cure, which sets the cross-linked material, while during the same process, heating the uncross-linked photoresist, which melts and reflows, using surface tension to form hemispherical structures, which may then be re-exposed (the inverse of the original negative space) and cured to form hardened lenses. For increased optical transparency, especially where solvent resistance is not required, the lens structures may remain unexposed to UV and hardened thermally.

According to a further aspect of the disclosure there is provided an article manufactured using the apparatus of any of the above aspects of the disclosure.

The article may be any one or more of:
a) unpatterned encapsulation or wafer bonding;
b) a free-standing structure;
c) a multilayer structure;
d) an aligned multilayer structure;
e) a substrate bound structure that can be either single or multilayer, aligned or not;
f) an active structure formed by the combination of partly bound and partly free-standing structures. Such an active structure may thus include a part or region that can move relative to another;
g) a structure that includes conductive elements;
h) an active structure that includes conductive elements.
i) a structure that contains transducer elements;
j) an active structure formed with the combination of transducer and conductive elements.

Further examples of such articles, as could be produced by the apparatus and method of the above statements, include the unpatterned encapsulation of electronics such as antennae, circuit boards, or electronic microcomponents.

Examples of single layer free-standing micro-componentry include articles such as miniature gears, cog wheels, springs, clips, lens holders, and stencils.

Examples of substrate bound structures include microstructured templates for precision stamps, electroplating, injection moulding, embossing, and soft lithography.

Examples of multilayer microstructures including hydrophobic surfaces, “gecko feet” type surfaces which may be used for precision robotics; or microfluidic chips.

Examples of active structures include cantilevers, plates, bridges, and membranes which are formed by selectively bonding part of a first photoresist to another photoresist to form a tether, while leaving part of the first photoresist free to move. Such active structures may comprise springs which are the basic components of MEMS springs, from which microsensors can be fabricated when combined with conductive and/or piezoelectric materials.

Further examples of such active structures include vibrational energy harvesters, which are micropillars acting as springs, combined with piezoelectric materials to convert vibrational energy to electric energy.

Examples of microsensors combined with vibrational energy harvesters include self-powered miniature sensors, as could be used for internet of things type hardware.

Further aspects of the disclosure, which should be considered in all its novel aspects, will become apparent from the following description.

### DESCRIPTION OF THE DRAWINGS

A number of embodiments of the disclosure will now be described by way of example with reference to the drawings in which:

FIGS. 1a and 1b are schematic side views of two variants of a multi-layer/laminated dry film photoresist, in accordance with aspects of the present disclosure;

FIG. 2 is a schematic view of a first embodiment of an apparatus configured to manufacture an article using, in this example, a dry film photoresist, in accordance with the present disclosure;

FIG. 3 is a schematic view of a second embodiment of an apparatus configured to manufacture an article using a dry film photoresist, in accordance with the present disclosure;

FIG. 4 is a schematic view of a third embodiment of an apparatus configured to manufacture an article using a dry film photoresist, in accordance with the present disclosure;

FIG. 5 is a schematic enlarged view of part of the apparatus of any of FIGS. 2 to 4 using a collimated light source;

FIG. 6 is a schematic showing steps of manufacturing an article using a multi-layer dry film photoresist, in accordance with this disclosure;

FIG. 7 is a view from above of part of an article produced using an embodiment of an apparatus in accordance with this disclosure, where the article has an undercut;

FIG. 8 is a view from underneath of part of the article of FIG. 7; and

FIGS. 9a to 9c are schematic side views of another embodiment of an apparatus configured to manufacture an article using a dry film photoresist, in accordance with the present disclosure.

### DETAILED DESCRIPTION OF SPECIFIC EMBODIMENTS

With reference to FIG. 1a, a dry film multi-layer/laminated photoresist P comprises, in this example, first and second layers of photoresist material 3, 7 on a carrier substrate 5. The substrate 5 may be considered to be a substrate in the following description. This disclosure covers multi-layer photoresists having any desired number of pre-laminated layers of photoresist material.

An example of photoresist material used in such a dry film photoresist P is as described in patent application US2006/0257785, the entire contents of which are incorporated herein by reference. An example of single layer dry film photoresist is made and sold by DJ MicroLaminates (formerly known as DJ DevCorp), under the brand name ADEX®. Other examples of such single layer dry film resists include the TMMF S 200 series (Tokyo Ohka Kyoto Co. Ltd.), DFR DF-1000, DF-2000 and DF-3000 series (Engineered Materials Systems), Ordyl SY DFR, or any series of these or other dry film resists. Other non-dry photoresists may also be used.

This disclosure relates to manufacture of articles using a multi-layer/laminated photoresist comprising a plurality of layers of photoresist material, where at least a first layer of photoresist material has a first sensitivity to radiation from an exposure source, and at least a second layer of photoresist material has a different sensitivity to radiation from the, or another, exposure source. The plurality of layers, which could comprise any number of layers, are pre-layered/pre laminated, so that both layers, or as many layers as required, of multi-layer/laminated photoresist can be exposed without moving the photoresist between exposing each layer, and without any laminating needing to occur during processing, or least with not every layer needing laminating after exposure. The multilayer/laminated photoresist may be supplied on a roll configured to be fed into the apparatus. This type of arrangement may be easier to use than handling sheets of photoresist. The apparatus could also use pre-laminated substrates.

With reference to FIG. 1b, the substrate 5 of the photoresist P may comprise a UV blocking and/or antireflective carrier sheet. The two layers 3, 7 of photoresist material have different sensitivities to radiation, as will be described in more detail below.

The photoresist P may comprise part of a photoresist cartridge comprising a rigid substrate to which the substrate 5 of the photoresist P is laminated.

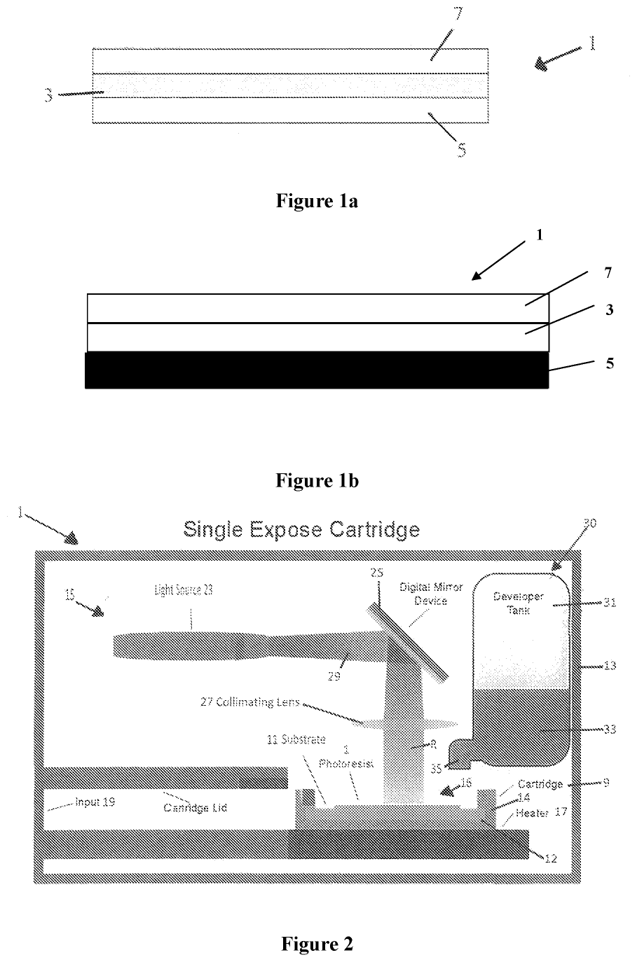

With reference to FIGS. 2 to 4, an apparatus 1 is configured to manufacture an article using a dry film photoresist P of the type described above, which may or may not be part of a cartridge 9. The apparatus 1 comprises:
a. a housing 13 configured to receive the photoresist P and locate the photoresist P in at least one operational position 16 in the housing 13;
b. an exposure system 15 configured to emit radiation R which is incident on the photoresist P when in the operational position 16; wherein:
   i. the exposure system 15 is configured to emit radiation having a first radiation characteristic to induce a change in one or more properties of the area(s) of at least the first layer of photoresist material exposed to the radiation.

The apparatus 1 may further comprise a heater 17 configured to subsequently heat and cure the dry film photoresist P to cross link the photoresist material layers 3, 7 to each other and/or to the substrate 5.

The housing 13 is configured to be radiation excluding, and may be UV excluding, at least to the extent that external radiation is sufficiently excluded from the housing 13 to prevent, or minimise polymerisation of the photoresist, at least when the dry film photoresist P is present, and further wherein the housing 13 is a clean housing configured to prevent contamination from entering the housing 13.

The housing 13 may comprise an inlet 19 configured to receive the photoresist P, which may be provided in or as a cartridge 9. The cartridge 9 may be pushed into the housing 13, or the housing may be provided with a feed device configured to feed/drive the cartridge 9 into the housing 13 automatically. The cartridge 9 is inserted into the housing 13 until it reaches an operational position, generally indicated 16. An end stop or the like, could be provided to prevent over-insertion of the cartridge 9. A feedback mechanism could be provided to indicate that the cartridge 9 is in the correct position. For example the feedback mechanism could generate a noise, vibration or emit a light to indicate the correct position of the cartridge 9.

In this example the exposure system 15 comprises a light source 23, and two light manipulator devices in the form of an inclined digital mirror 25 and a collimating lens 27. The arrangement is such that light emitted from light source 23 follows a light path 29 which bends through 90° before being incident on the photoresist P. The collimating lens 27 helps minimise unwanted scattering of light within the housing 13.

The heater 17 in this example comprises a heater plate on which the cartridge 9 rests when in the operational position 16.

The apparatus 1 further comprises a developer unit 30 comprising a developer storage tank 31 in which a volume of developer fluid 33 is stored. In this example, the developer unit 30 is located inside the housing 13. In other examples the developer unit 30 could be separate from apparatus 1. The developer fluid 33 is dispensed from the tank 31 via a dispenser outlet 35 which may comprise an outlet pipe configured to simply drop developer fluid onto the cartridge 9, or may comprise a nozzle configured to generate a spray or mist of developer fluid 9. In other examples, development could be carried out within a subunit of the housing 13, such as the cartridge itself, or in a removable developer unit removeably mounted on the housing 13. The cartridge development can be used to protect the user from contact with the developer solvent. Development can make use of hot water which can be heated by heater 17, or by an external heat source, such as a microwave source. A bath, mist or spray system may be used, with or without developer fluid recirculation.

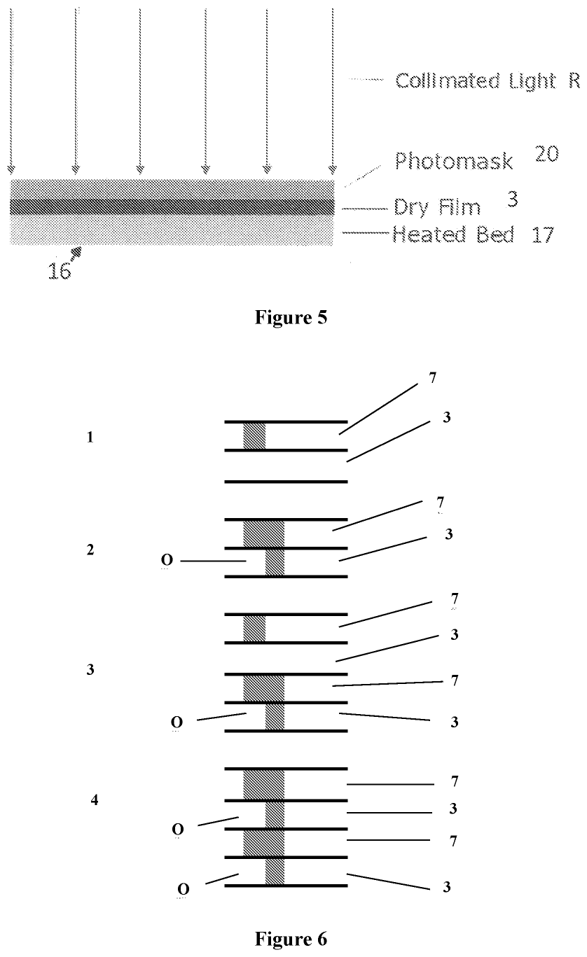

With additional reference to FIG. 5, the apparatus 1 or the cartridge 9 is provided with a patterning system 20 configured to form a pattern on the photoresist material 3 such that a region or regions of the photoresist material 3 is/are exposed to light from the light source 23. The patterning system 20 in this example comprises a photomask placed on top of the photoresist P. That exposure to light through the photomask 1 liberates the photo-initiator in the photoresist material 3 to form the desired pattern on the photoresist material and to allow some of the photoresist material 3 to be removed using developer fluid 33 from tank 31. Prior to development, but after exposure, the cartridge 9 is heated by the heater 17 to cure the photoresist material to cross link it to the cartridge substrate 11. After a suitable cool down period, developer fluid 33 is dispensed from tank 31 onto the cartridge 9, within the cartridge wall 14. The cartridge base and wall 14 form a bath of developer fluid in which the photoresist P sits. The developer fluid 33 causes the desired parts of the photoresist material 3 to be removed. The remaining photoresist material may then be baked, by reactivating the heater 17 for a predetermined duration and a temperature.

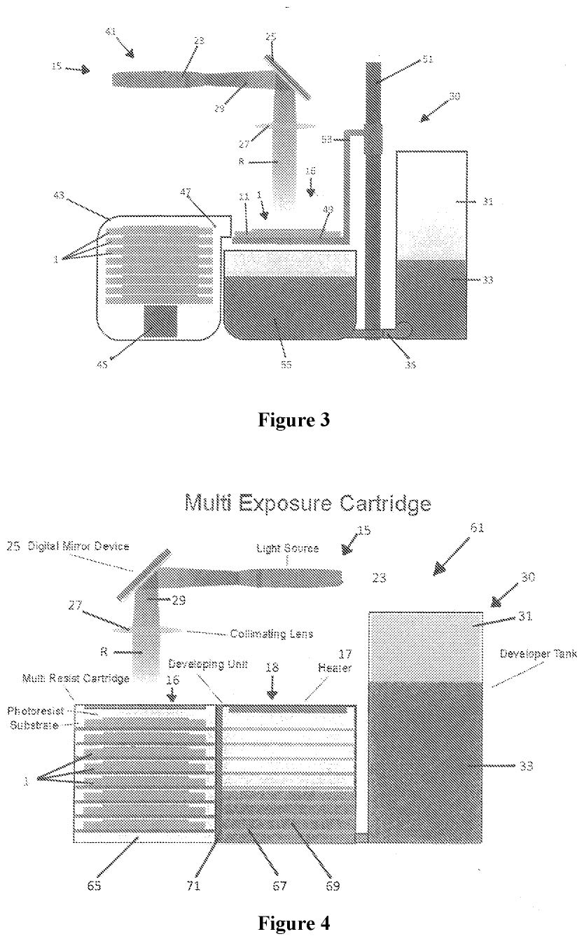

Referring to FIG. 3, a further apparatus 41 comprises similar features to those of apparatus 1. Like references have been used for like features. In this example, a photoresist storage device 43 is provided, removeably mounted in housing 13. A plurality of photoresists P are in this example stacked in the device 43 on a height adjustable rack 45. The rack 45 is configured to raise the uppermost photoresist P to a position aligned with the operational position in the housing 13 and to deliver that uppermost photoresist P to the operational position via a compartment outlet 47. The operational position in this example is defined by a platform 49 in the housing 13, which is movably mounted on a post or rail 51 via an arm 53 so that the platform 49 and photoresist P can be moved up and down within the housing 13. The exposure system 15 is as described above. In this example, the developer storage tank 31 feeds developer fluid 33 to a developer bath 55 directly below the platform 49. The platform 49 can be lowered into the bath 55 to develop the photoresist P, and then raised out of the bath 55 once developed. Raising and lowering the platform 49 also raised the photoresist P towards and away from the collimating lens. In this example, the heater 17 is in the form of an oven which heats the interior of the housing 13, at least in the region of the platform 49 and photoresist P. Apparatus 41 therefore provides batch processing of multiple photoresists P, where the batch processing may be fully or partially automated.

Referring to FIG. 4, a further apparatus 61 comprises similar features to those of apparatus 41. Like references have been used for like features. In this example, photoresist storage device 43 is again provided in housing 13. A plurality of photoresists P are stacked in the device 43 on rack 65. The rack 65 is configured to transfer each photoresist P laterally across into a second rack 67. The second rack 67 is contained within a developer bath 69, with a movable closure 71 located between the two racks 65, 67, and movable to an open position to allow a photoresist P on rack 65 to be transferred to second rack 67, and to subsequently close to form a sealed side wall of bath 69. In this example apparatus 61 provides a first operational position 16 for each photoresist P in rack 65, and a second operational position 18 for each photoresist P in second rack 67. The uppermost photoresist P in rack 65 is exposed to radiation from exposure source 23. Once exposed, movable closure 71 opens, and the photoresist P that has been exposed is transferred into second rack 67. The process repeats for all of the photoresists P in rack 65, which are sequentially exposed to exposure source 23. Once all of the exposed photoresists P have been transferred to second rack 67, the closure 71 closes to form the developer bath 69 which is filled with developer fluid 33 from tank 31 to simultaneously develop all of the photoresists P in second rack 67. In this example heater 17 comprises a heater plate located at the top of second rack 67.

In these examples, the housing 13 comprises a cuboidal box. The housing may comprise any self-contained, preferably portable, radiation blocking (in some examples UV blocking), clean container or box. In some examples, the housing 13 is shaped and dimensioned to be form a desktop unit. In one example, the dimensions of such a box are 60 cm by 40 cm by 75 cm with a weight of around 10 kg. Such a unit might be useful for prototyping or other lower resolution manufacture. In other examples, the housing 13 may be somewhat larger in order to be able to produce higher resolution articles. In any example, the housing 13 is such that it is considerably smaller than a traditional clean/yellow room, and is configured to be a unit contained in room of a building rather than itself being a room of a building. The housing 13 may therefore be relatively small and compact. The housing 13 may be configured to be freestanding.

The apparatus may use any photoresist P that comprises photoresist material applied to a substrate. It may in some examples be preferable to use a dry film photoresist, and in some examples to use one or more Thick Dry Film photoresist Sheets (TDFS) of the type manufactured by DJMicroLaminates for example.

The apparatus patterns upon exposure to radiation from an appropriate energy source of the exposure system 15. The photoresist sheets 1 are preferably handled between disposable carrier sheets 5. If the carrier sheets and/or cartridge are UV blocking, this facilitates easy handling of the photoresists P in a manner similar to a printer cartridge or the like, without requiring clean/yellow room conditions. The photoresist sheets 1 can be positive or negative toned, chemically amplified or not, image reversal or not. Alternative sources of photoresist such as spin-coatable, dip, spray, rollable, screen printable, slot die or doctor-bladed etc photoresists may also be used.

The exposure system 15 may comprise an electron or e-beam apparatus configured to bombard the photoresist with a beam of targeted, focused electrons. Such an e-beam apparatus could be configured with a voltage controller configured to control and vary the voltage of the e-beam. This can be used to control and vary the penetration depth of the e-beam into the photoresist, and therefore create sophisticated articles having features where differing depth of photoresist have been exposed.

The exposure system 15 may comprise a plurality of exposure apparatus configured to provide multiple sources of radiation of the same type, or multiple sources of radiation of different types. For example the exposure system 15 could comprise an e-beam apparatus and a UV radiation source. This would enable the exposure system 15 to expose the photoresist to different types of radiation, either simultaneously or sequentially.

Use of an e-beam exposure system may also enable patterning to take place at a relatively high resolution of for example, below 10 nm resolution. Another advantage is that non-transparent photoresists (i.e. photoresists with relatively heavy loadings of particles) may be used.

When used, the substrate 5 and protective sheet (not shown), also known as photoresist carrier sheets, can remain in place to prevent particulates from reaching the photoresist itself, to control surface tension during processing and as a surface for direct patterning (avoiding the need for a separate photomask or the like).

As the housing 13 is radiation excluding, it also prevents radiation source exposure to the user.

The patterning can be from a photomask 20 as described above. This mask can be a high quality glass photomask, but any high contrast but transparent media may be used as a conformal print mask to improve resolution. Greyscale masks can be used. Alternative methods of patterning include maskless patterning methods which can use digital light processing (DLP) with digital micromirror devices (DMD) or laser based printing techniques such as those used with a laser printer, or for writing compact discs or digital video discs for example. A suitable projector or laser can be provided configured to automatically expose the photoresist in the desired pattern. The projector or laser may be operative according to a suitable electronic pattern file from an external data storage device, or generated electronically using the controller of the apparatus, or wirelessly from a remote computer or device.

The heater 17 could be, for example: an infrared heater, hotplate or heater base, or an oven. As the heater 17 is contained in the housing 13, it also prevents the user from direct contact with heat, eliminating a further hazard. The heater 17 may be sandwiched between plates of a photoresist support.

The photoresist itself could be deposited by other means including slot die coating, spin coating, spray coating and/or laser assisted deposition. In the latter, a laser beam can be targeted at photoresist material to deposit photoresist material on a substrate in only the areas which require pattern or support, rather than full coverage of the substrate by lamination. Consequently the amount of photoresist required can be significantly reduced as compared to using a pre-laminate strip of sheet of photoresist. Such a deposition system comprises a laser beam generator, and means to direct the laser from the laser beam generator at a source of photoresist. The laser causes droplets of photoresist to fall from the source of photoresist onto the substrate below. Once sufficient photoresist is present on the substrate, the above described article manufacturing process can take place. Spin-coating may be useful for a first deposition layer which could include a dye loaded photoresist.

The apparatus 1 can be controlled using one or more manual or automated controllers, either by manual switched input, timers, electromechanical systems or using one or more microcontroller. The apparatus 1 can also be integrated with the internet of things, for example via a suitable Wi-Fi transceiver and controlling software/hardware in the apparatus 1.

Development could be carried out in the box, or within a subunit of the box, such as the cartridge itself. Development can be arranged to protect the user from contact with the developer solvent. Development can make use of hot water which can be heated from the box heat source, or external source, or a microwave source. A bath, mist or spray system may be used, with or without recirculation.

For wafer bonding or encapsulation, where antennae, circuit boards or micro-components are fully coated and flood exposed for protection, no patterning system is required. For positive toned resists, no heating system is required.

The housing 13 can be manufactured from a radiation, and preferably UV, blocking material such as custom Polycarbonate. The housing 13 may be manufactured using any one or more of: 3D printing; laser cutting or milling. The housing may be provided with a closure in the form of a door or the like to close the housing 13 when the photoresist P is in the operational position. The closure may be provided with an interlock in the form of an electronic or magnetic lock controlled by the controller to lock the closure when the photoresist P is in the operational position.

The UV radiation emitted by the exposure system may be from any of the following light sources: Fluorescent AC or DC; LED, laser. The exposure system may comprise a safety system configured such that UV radiation can only be emitted when the photoresist P is in the operational position and the housing 13 is in a closed condition, that is, the housing 13 is UV blocking. One or more sensors may be provided configured to generate signals indicative of these factors, the controller only activating the exposure system when the sensor(s) indicate that one or both conditions are fulfilled. The exposure system may include a cold start system configured to warm up the UV source prior to exposing the photoresist to UV radiation. A suitable shutter may be provided.

The heater 17 may comprise a 3D Printing Bed and associated heater driver.

The controller may comprise a microcontroller. One example is an Arduino microcontroller. The controller may comprise any one or more of the following features: timer, thermometer; thermocouple; IR noncontact; thermistor; light detector; LDR with filter. The controller may be internal of the housing 13, externally mounted on the housing 13, or in communication with components of the housing 13 via wired or wireless connection. One or more sensors may be provided to generate sensor signals indicative of one or more characteristics of the apparatus, the signals being processed by the controller.

The apparatus 1 power supply may include an AC-DC voltage converter, a transformer and may be internal or external of the housing 13. One or more relays may be provided between the controller, power supply and one or more components, such as the heater 17 for example.

The apparatus 1 may use dry film photoresists as previously described as the consumable in the manufacturing process. The dry film photoresists may be supplied as different thicknesses of photoresist between two removable carrier sheets. This in itself replaces several steps of conventional lithography.

The UV and heat sources may be controlled manually with timer and power switches. In a more automated apparatus, a microcontroller controls the exposure and cure profiles. In each case, the exposure and cure times depend on two primary input parameters: the thickness of the dry film resist sheet (which determines the exposure and curing time) and any substrate material (if present) (which determines the curing profile). The user can operate the apparatus by first inserting the cartridge, and inputting the parameters to select the appropriate length of UV exposure (which liberates the photoinitiator), then heat profile (which cross-links the photoresist and bonds to the substrate). Once inserted into the housing, the cartridge can sit in one operational position which alternately exposes then cures in situ. The entire photolithographic processing takes place in the housing, with carrier (or pattern) sheet and backing sheet (if used) in place. After cooling (which may be indicated by the box), the user removes the photoresist, discards the top carrier (pattern) sheet (or both sheets to speed development for freestanding structures) and is ready to develop.

The apparatus 1 may be configured for multiple applications, including, for example, production of electroforming moulds, microfluidic moulds including grey-scaled moulds, or free standing printed structures.

Referring to FIG. 6, four steps of producing an article in accordance with the current disclosure are shown. In step 1, the photoresist P is exposed as shown to radiation to which only the top layer 7 is sensitive. In Step 2, the photoresist P is exposed to radiation to which both layers 7, 3 are sensitive. In this way an overhang O can be created by applying the radiation to the layers, 3, 7 using a suitable pattern. In steps 3 and 4 the same process can be repeated using a second multilayer/laminated photoresist P, and the two photoresists P laminated together to define a composite article having two overhangs O.

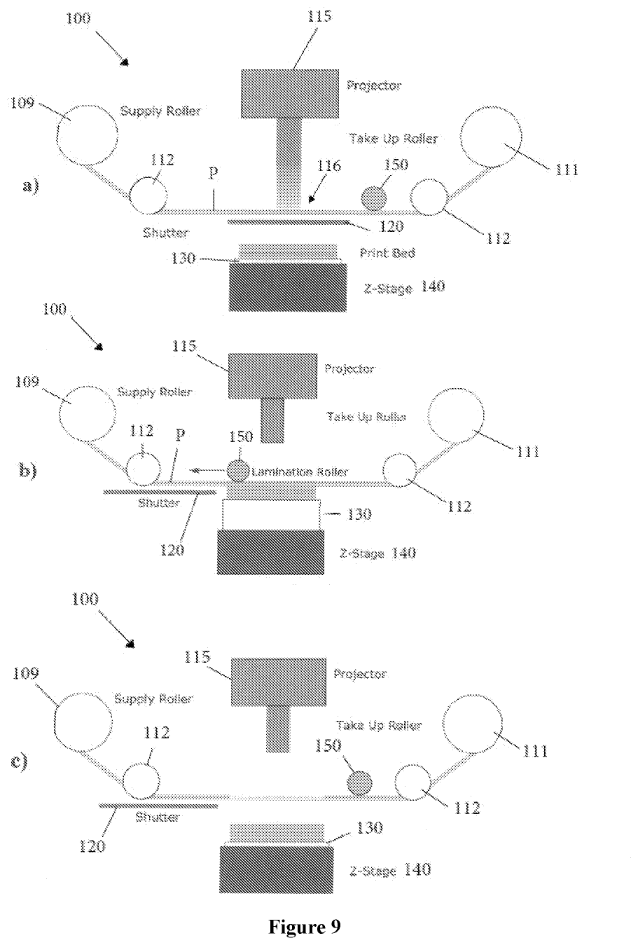

With reference to FIG. 9, an apparatus 100 is configured to manufacture an article using a dry film photoresist P of the type described above, which may or may not be part of a cartridge 9. In this example the cartridge comprises a roll of photoresist mounted on supply roller 109. The apparatus 100 comprises:
a. a housing configured to receive the photoresist P and locate the photoresist P in at least one operational position 116 in the housing;
b. an exposure system 115 configured to emit radiation R which is incident on the photoresist P when in the operational position 116; wherein:
   ii. the exposure system 115 is configured to emit radiation having a first radiation characteristic to induce a change in one or more properties of the area(s) of at least the first layer of photoresist material exposed to the radiation.

The apparatus 100 further comprises a lamination roller 150, configured to subsequently bond the dry film photoresist P to the photoresist material layers 3, 7 to each other and/or to the substrate 5.

The housing, as above, is configured to be radiation excluding, and may be UV excluding, at least to the extent that external radiation is sufficiently excluded from the housing to prevent, or minimise polymerisation of the photoresist, at least when the dry film photoresist P is present, and further wherein the housing is a clean housing configured to prevent contamination from entering the housing.

In this embodiment, the photoresist P extends across the apparatus 115 between supply roller 109 and a take-up roller 111. The relative speeds of rotation of the supply rollers 109 and take-up rollers 111 are controlled such that the tension of the strip of photoresist P is maintained at a desired level. Intermediate rollers 112 may also be used.

The exposure system 115 comprises a projector configured to direct radiation to an exposed surface of the photoresist P as shown in FIG. 9a. In this position, a movable shutter 120 is moved to a position adjacent to an opposed surface of the photoresist P, so as to be located between the photoresist P and an adjacent substrate 130. Substrate 130 is movable towards and away from the photoresist P via being removably located on a Z-stage 140, the Z-stage 140 being configured to move the substrate 130 in the X, Y and/or Z axes relative to photoresist P.

Once exposed, and with reference to FIG. 9b, the shutter 120 is moved away, and the Z-stage 140 controlled to move the substrate 130 into contact with the non-exposed surface of the photoresist P. A heated lamination roller 150 is then rolled across the exposed surface of the photoresist P, laminating the photoresist P to the substrate 130, and bonding the exposed (or non-exposed) region or regions of the photoresist P to the substrate 130.

Once laminated, and with reference to FIG. 9c, the strip of photoresist P is retracted by winding the photoresist a predetermined amount onto the take-up roller 111, leaving a new portion of photoresist P in the operative position between the substrate 130 and the projector 115.

The above process is then repeated, to form another layer of the article, to be exposed and laminated to the other layers on the substrate 130. After all steps are completed, the article is cured and developed. This step may take place either within the apparatus, or externally as part of a post-processing step, but is still an essential part of the method.

### Example 1

In one example we provide a dry film pre-laminated photoresist made up of two layers of photoresist material 3, 7, nominally each approximately 5 μm thick. In this example, the top layer 7 is more sensitive to radiation in the form of UV light than the bottom layer 5. This creates a photoresist that can selectively allow or not allow exposure to the laminated layer beneath it.

Such a photoresist can be used to manufacture a 3D printed article with an overhang. Where there is an overhang, the top layer 7 can be exposed to a lower intensity light (or light of a different wavelength) that does not activate the bottom layer 3. Where there is no overhang a higher intensity light (or light of a different wavelength) can be used to expose through both layers.

Thus, the two layers of photoresist material have different sensitivities to a characteristic of the radiation from the exposure source. Consequently, in this example, a single exposure source, or at least a single type of radiation, can be used to have a different effect on each layer 3, 7 of photoresist material.

The two layer photoresist will enable lamination of the two layers 3, 7 first and then expose —rather than expose (with a shutter), align and then laminate as with prior art systems. Consequently, the alignment of each layer will not be dependent on mechanical processes, reducing the complexity and cost of the apparatus, but can instead be performed optically to the same fixed points for each layer (i.e. each layer does not have to be separately positioned prior to exposure). The pattern will also not get distorted by the lamination process as the pattern is only exposed after lamination. Overall, prelamination in this way, using photoresist material layers having different properties, improves the accuracy, and ease, of manufacture of multi-layer articles.

The two layer (in this example negative acting) photoresist P could have any one or more of the following:
a) The same photopolymerization initiators in each layer but with different concentrations.
b) Different photopolymerization initiators in each layer.
c) A layer with a loading of nano-particles that have a selective absorption peak at a set wavelength. The layer may be a single layer, or a layer comprising part of a photoresist with multiple layers.
d) A layer with a particle or dye loading that partially prevents deep exposure and/or exposure of the layer underneath depending on the intensity of the light. The layer may be a single layer, or a layer comprising part of a photoresist with multiple layers.

The photoresist could then be exposed with different intensities of light radiation or exposed with different wavelengths of light. The lower intensity or one range of wavelengths of light will only (or predominately) activate the top layer 7 of the photoresist P in areas for example where an overhang is required. The higher intensity or other range of wavelengths of light will activate both layers 3, 7 of the photoresist P in areas where an overhang is not required but a bond of layer 3 to the previously laminated and exposed photoresist layer 7 is required.

The next layer or layers would be laminated on and the process repeated. Thus an article could be manufactured from a stack of multilayer/laminated photoresists P.

### Example 2

In this example, loading of metal or ceramic particles, or dye, in a layer of photoresist could also prevent or at least control exposure of layers laminated beneath it. The loading of particles can be any desired proportion of the photoresist material, for example the particles might comprise 0.1-50% of the photoresist material.

The layer of metal/ceramic or dye loaded photoresist will also have the same advantages as described above, in providing a layer of photoresist material having a different sensitivity to radiation than adjacent or other layers of a multi-layer photoresist sheet. Such a variation in sensitivity enables the layers to activate differently when exposed to a common or single source of radiation, or to activated differently when exposed to multiple sources of radiation configured to emit radiation having different characteristics.

Consequently, this enables the multi-layer photoresist to be laminated first and then exposed —rather than expose (with a shutter), align and then laminate. The alignment of each layer of photoresist material will not be dependent on mechanical processes but will be performed optically to the same fixed points for each layer. The pattern will also not get distorted by the lamination process as it is exposed after lamination.

A metal or ceramic loaded article could form the basis of making relatively small metallic or ceramic parts if the resin binder is burnt off and the metal/ceramic particles sintered together, forming conductive metal or insulating ceramic structures. With shrinkage small parts will be become smaller, producing higher value miniaturised structures.

Providing a multi-layer photoresist having at least one layer which reacts differently to radiation exposure to one or more other layers of photoresist material can enable articles to be made more easily and precisely via exposure from a single source of radiation. In other words, the properties of one, some or each layer can be selected to achieve the desired shape and configuration of article, using an exposure system configured to emit radiation having a consistent or single radiation characteristic, for example, radiation of a single wavelength, or intensity.

The single layer of, for example, negative acting photoresist could also or alternatively be exposed with radiation having different properties, such as different intensities of light for example. Such radiation could be provided by a single source of radiation configured or controlled to selectively generate radiation having different properties, or could be provided by multiple radiation sources each configured to controlled to generate radiation having different properties.

For example, dependent upon the selection of the radiation characteristics of the top layer of photoresist material, the lower intensity of light will only activate the top layer of the photoresist P in areas where an overhang is required. A higher intensity of light will activate deeper into the photoresist P to areas where a bond to the previously laminated and exposed photoresist. The next layer can be laminated on and the process repeated.

### Example 3

A two layer photo resist was created by laminating a sheet of DF 3510 dry film photoresist onto a substrate and then a sheet of photoresist DF 2020 was laminated on top of this. This created a two layer photoresist material with each layer having different exposure sensitivity characteristics.

Lines were patterned using a MicroTech LW405A laser writer in one direction on this multilayer photoresist using a 100 mW 406 nm laser and then a further set of lines were patterned at 90 degrees to these lines using a 18 mW 378 nm laser.

After exposure the multilayer photoresist was cured at 100° C. for 10 minutes to cross-link the structure.

Following curing, the structures were developed in cyclohexanone to remove all uncross-linked material.

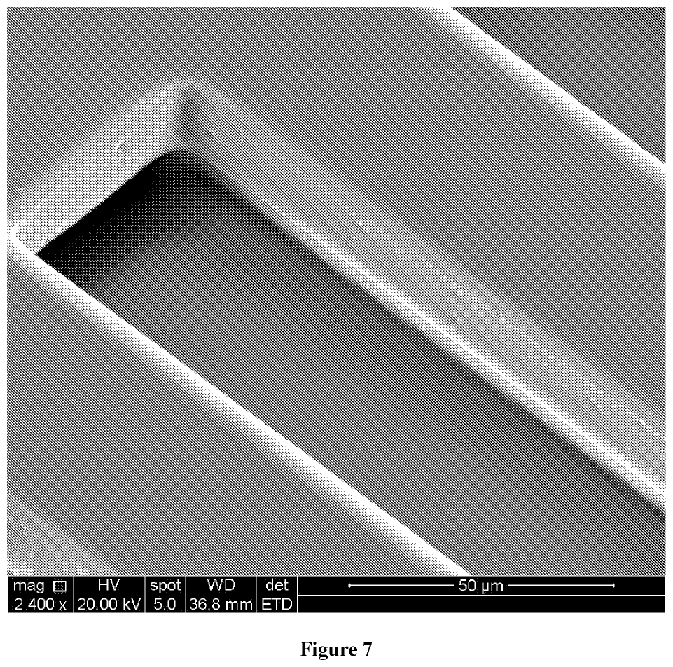

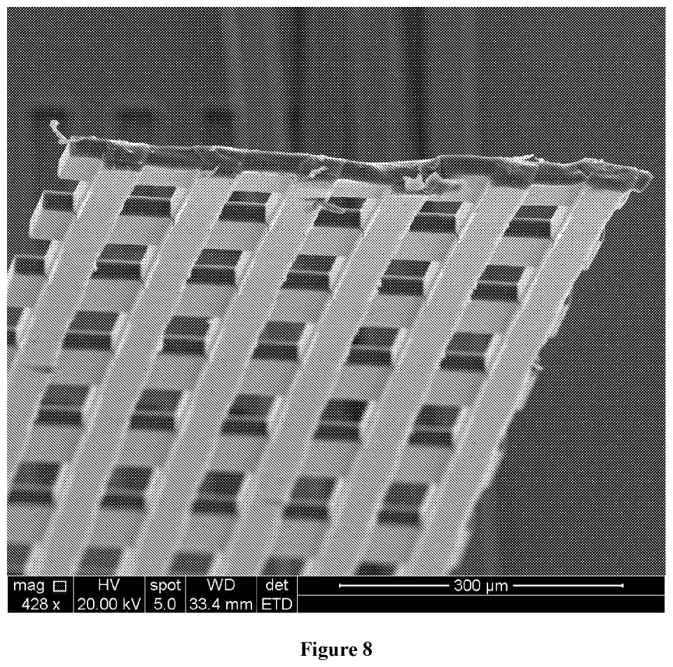

The resulting images shown in FIG. 6 shows a view from the top with a clear over hang in the top left of the image. The view from the bottom of FIG. 7 shows the pattern of two sets of intersecting lines where one set of lines have full depth and the others have only partial depth—the lines extending generally vertically in the image are thicker than the lines extending generally horizontally.

The above described processes can be implemented using some or all of the features of the apparatus as described above and/or as described in our earlier patent application PCT/NZ2018/050030, in particular the aspects of the apparatus configured to position and/or retain the photoresist in the operational position, the exposure system, and the heater.

Because in this disclosure, the photoresist P is exposed after having been laminated into a multi-layer form, some of the aspects relating to feeding the photoresist P into the apparatus, and/or laminating single sheets of photoresist onto one another, may not be required. In line with this disclosure, multiple layers of pre-laminated photoresist may be exposed whilst the photoresist P is retained in the operational position in the apparatus.

Whilst the above examples refer to manufacture of an article having an overhang, the above described apparatus, photoresist and method, can be used to manufacture any article.

Unless the context clearly requires otherwise, throughout the description, the words “comprise”, “comprising”, and the like, are to be construed in an inclusive sense as opposed to an exclusive or exhaustive sense, that is to say, in the sense of “including, but not limited to”.

Although this disclosure has been described by way of example and with reference to possible embodiments thereof, it is to be understood that modifications or improvements may be made thereto without departing from the scope of the disclosure. The disclosure may also be said broadly to consist in the parts, elements and features referred to or indicated in the specification of the application, individually or collectively, in any or all combinations of two or more of said parts, elements or features. Furthermore, where reference has been made to specific components or integers of the disclosure having known equivalents, then such equivalents are herein incorporated as if individually set forth.

Any discussion of the prior art throughout the specification should in no way be considered as an admission that such prior art is widely known or forms part of common general knowledge in the field.

1. An apparatus configured to manufacture an article using a multi-layer and/or laminated photoresist comprising a plurality of layers of photoresist material, where at least a first layer of photoresist material has a first sensitivity to radiation, and at least a second layer of photoresist material has a different sensitivity to radiation, the apparatus comprising:
a. a housing configured to receive the photoresist and locate the photoresist in at least one operational position in the housing;
b. an exposure system configured to emit radiation which is incident on the photoresist when in the operational position; wherein:
i. the exposure system is configured to emit radiation having a first radiation characteristic to induce a change in one or more properties of the area(s) of the first layer of photoresist material exposed to the radiation; and wherein
ii. the first radiation characteristic is configured not to induce a change, or to induce a different change, in one or more properties of at least a different one of the layers of photoresist material.

2. The apparatus of claim 1 wherein the exposure system is configured to emit radiation having a second radiation characteristic, which is different to the first radiation characteristic, to induce a change in one or more properties of the area(s) of at least a different one of the layers of photoresist material exposed to the radiation.

3. The apparatus of claim 1 or claim 2 further comprising a heater configured to heat the photoresist material to cure the photoresist material when the photoresist is in the operational position, or is in a different operational position in the housing.

4. The apparatus of any one of the preceding claims wherein the housing is radiation excluding such that external radiation cannot enter the housing at least to the extent that the external radiation is sufficiently excluded from the housing to prevent, or minimise polymerisation of the photoresist material, and further wherein the housing is a clean housing configured to prevent unwanted contamination from entering the housing, at least when the photoresist is located in the or each operational position.

5. The apparatus of any one of the preceding claims wherein the apparatus is either configured to receive the multi-layer/laminated photoresist, or further comprises means to pre-laminate the multiple layers of photoresist material to form the multi-layer/laminated photoresist, prior to the multi-layer/laminated photoresist being exposed to radiation from the exposure system.

6. The apparatus of any one of the preceding claims wherein the first and second radiation characteristic of the radiation emitted by the exposure system is any one or more of the:
a. intensity of the radiation;
b. wavelength of the radiation;
c. duration of the radiation;

7. The apparatus of any one of the preceding claims configured to use a dry film photoresist.

8. The apparatus of any one of the preceding claims wherein the apparatus is hand portable.

9. The apparatus of any one of the preceding claims dimensioned and configured as a desk-top apparatus.

10. The apparatus of any one of the preceding claims configured to manufacture an article with feature sizes of 0.5 microns or less, 2 microns or less, four microns or less, or 20 microns or less, and/or a scale of at least 1 cm, 5 cm, 10 cm, 15 centimetres, or 50 cm or more.

11. The apparatus of any one of the preceding claims wherein the exposure system comprises at least one exposure source, wherein the exposure source comprises a light source selected from any one: a UV fluorescent tube or bulb, an LED or LED array, a laser, a projector, and/or a digital micromirror device (DMD).

12. The apparatus of claim 11 comprising multiple exposure sources, each source configured to emit radiation having a different radiation characteristic.

13. The apparatus of claim 11 wherein the exposure source is configured or may be controlled to selectively emit radiation having different radiation characteristics.

14. The apparatus of any one of the preceding claim wherein the exposure source comprises an electronic-beam apparatus configured to emit a beam of electrons onto the photoresist.

15. The apparatus of any one of the preceding claims comprising at least one controller configured to control the exposure system.

16. The controller may be configured to control any one or more of:
a. the intensity, and/or duration and/or timing of the radiation emitted from the exposure system; and/or
b. any one or more of the temperature, duration, timing and/or heating/cooling rate of a heater of the apparatus; and/or
c. an exposure profile and/or a heater profile.

17. The apparatus of claim 14 or claim 15 wherein the controller is configured to receive one or more inputs indicative of one or more properties of the article to be manufactured and/or of the dry film photoresist, and to control the exposure system profile and/or heater profile accordingly.

18. The apparatus of any one of the preceding claims wherein the photoresist is deposited on a substrate that is subsequently exposed to the exposure system.

19. The apparatus of claim 18 wherein at least one layer of photoresist is deposited on the substrate using any one or more of:
a. slot die coating;
b. spin coating;
c. spray coating;
d. electrospinning
e. inkjet; and/or
f. laser assisted deposition.

20. The apparatus of claim 19 comprising a source of photoresist, and an depositor configured to deposit photoresist from the source of photoresist onto a substrate.

21. An apparatus configured to manufacture an article using a multi-layer/laminated photoresist comprising a plurality of layers of photoresist material, where at least a first layer of photoresist material has a first response to radiation, and at least a second layer of photoresist material has a different response to radiation, the apparatus comprising:
a. a housing configured to receive the photoresist and locate the photoresist in at least one operational position in the housing;
b. an exposure system configured to emit radiation which is incident on the photoresist when in the operational position; wherein:
i. the exposure system is configured to emit radiation having a first radiation characteristic to induce a change in one or more properties of the area(s) of the first layer of photoresist material exposed to the radiation; and wherein
ii. the first radiation characteristic is configured not to induce a change, or to induce a different change, in one or more properties of at least a different one of the layers of photoresist material.

22. A multi-layer/laminated photoresist configured for use with the apparatus of any one of claims 1 to 21, the multi-layer/laminated photoresist comprising a plurality of layers of photoresist material, where a first layer of photoresist material has a first sensitivity to radiation, and at least a second layer of photoresist material has a different sensitivity to radiation.

23. The photoresist of claim 22 comprising one or more cover sheets, wherein one or both cover sheets is removable.

24. The photoresist of claim 22 wherein the sensitivity to radiation is sensitivity to any one or more of:
a. UV sensitivity;
b. layer thickness;
c. sensitivity to radiation intensity; and/or
d. sensitivity to radiation wavelength.

25. The photoresist of any one of claims 22 to 24 wherein the sensitivity to radiation of at least one layer is varied from at least one other layer by the inclusion of any one or more of the following in the at least one layer:
a. an optical dye capable of modifying UV absorption;
b. particles;

26. The photoresist of claim 25 wherein the particles are selected from any one or more of the following materials, or composite particles comprising one or more of the following materials:
a. metal;
b. ceramic;
c. magnetic;
d. piezoelectric;
e. thermochromic;
f. photochromic;
g. antimicrobial;
h. any other functionalised nanomaterial.

27. The photoresist of any one of claims 22 to 26 comprising the same photopolymerization initiators in each layer but with different concentrations.

28. The photoresist of any one of claims 22 to 27 comprising different photopolymerization initiators in each layer.

29. The photoresist of any one of claims 22 to 28 comprising a top layer with a loading of nano-particles that have a selective absorption peak at a set wavelength.

30. The photoresist of any one claims 22 to 29 comprising a top layer with a particle or dye loading that partially prevents deep exposure and/or exposure of the layer underneath depending on the intensity of the radiation.

31. A system for manufacturing an article using dry photoresist comprising a photoresist layer on a substrate, where the substrate may be the photoresist carrier sheet, the system comprising the apparatus of any one of claims 1 to 21, and a photoresist of any one of claims 22 to 30.

32. A method of manufacturing an article using a multi-layer/laminated photoresist comprising a plurality of layers of photoresist material, where at least first layer of photoresist material has a first sensitivity to radiation, and at least a second layer of photoresist material has a different sensitivity to radiation, the method comprising steps of:
a. inserting the photoresist into a housing of a manufacturing apparatus;
b. using an exposure system in the housing to emit radiation which is incident on the photoresist material when in the operational position, wherein:
i. the exposure system is configured to emit radiation having a first radiation characteristic to induce a change in one or more properties of the area(s) of the first layer of photoresist material exposed to the radiation; and wherein
ii. the first radiation characteristic is configured not to induce a change, or to induce a different change, in one or more properties of at least a different one of the layers of photoresist material.

33. The method of claim 32 comprising the further step of:
a. controlling a heater, also in the housing, to subsequently heat the photoresist material to cross link the photoresist material to the substrate.

34. The method of claim 32 wherein the exposure system is configured to emit radiation having a second radiation characteristic, different to the first radiation characteristic, to induce a change in one or more properties of the area(s) of at least a different one of the layers of photoresist material exposed to the radiation.

35. The method of claim 32 wherein the housing is radiation excluding such that external radiation cannot enter the housing at least to the extent that the external radiation is sufficiently excluded from the housing to prevent, or minimise polymerisation of the photoresist material, at least when the photoresist is present, and further wherein the housing is a clean housing configured to prevent unwanted particles and/or other contaminants from entering the housing.

36. The method of claim 32 wherein the photoresist layer can be either used as received as a dry film photoresist, or may be subject to a pre-processing step whereby the apparatus dries the photoresist layer by removal of the solvent, such that the dry photoresist can then be processed as above.

37. An article manufactured using the apparatus of any one of claims 1 to 21, or the method of any one of claims 32 to 36.

38. A system substantially as described herein and as shown in any one of FIGS. 1 to 5.

39. An article substantially as described herein.

40. A photoresist substantially as described herein.

41. A method substantially as described herein and as shown in any of FIGS. 1 to 7.
